(19) United States
(12) Patent Application Publication
(10) Pub. No.: US 2013/0175677 A1
(43) Pub. Date: Jul. 11, 2013

(54) Integrated Circuit Device With Wire Bond Connections

(71) Applicants: Wade Chang, New Taipei City (TW); Ming-Tsung Lee, New Taipei City (TW); Sean Kuo, Taipei City (TW)

(72) Inventors: Wade Chang, New Taipei City (TW); Ming-Tsung Lee, New Taipei City (TW); Sean Kuo, Taipei City (TW)

(73) Assignee: TEXAS INSTRUMENTS INCORPORATED, Dallas, TX (US)

(21) Appl. No.: 13/345,460

(22) Filed: Jan. 6, 2012

(51) Int. Cl. H01L 23/495; H01L 23/498; H01L 21/56

(52) U.S. Cl. 257/673; 438/124; 257/737; 257/E23.052; 257/E23.068; 257/E21.502

(57) ABSTRACT

An integrated circuit device including: a first die, a first die bonding pad formed on the first die, a gold bump electrode formed on the first bonding pad, and a copper wire having a first end portion stitch bonded to the gold bump electrode; and a method of forming the integrated circuit device.

### BACKGROUND

Semiconductor integrated circuits have become ubiquitous in modern electronics because of their small size, low cost and reliability. In recent years, multi-chip modules (MCM's) containing more than one integrated circuit die have become widely used because complex components can be made by simply connecting multiple dies to each other within a single package. Dies are often connected through wire bond connection of a bonding pad on one die with a bonding pad on another.

It is conventional to connect a bonding pad of one die with a bonding pad on another die with a small diameter gold wire. A gold bump electrode is formed on the bonding pad of a first die. A gold wire is ball bonded at one end to the bonding pad of a second die. The other end of the gold wire is then stitch bonded to the gold bump electrode on the first die. During this process, the gold wire is paid out from a device known as a capillary. Stitching is performed by pressing the capillary against the gold bump electrode and a portion of the gold wire that is positioned on top of the bump electrode. Heat and ultrasonic vibration are usually applied at the same time. The pressure, heat and vibration cause the gold wire and the gold bump to partially melt and merge together to form the stitch bond.

### BRIEF DESCRIPTION OF THE DRAWINGS

FIG. 1 is a sectional view of a multiple chip module (MCM).

FIG. 2 is a top plan view of the MCM of FIG. 1.

FIG. 3 is a detail sectional view of a bonding pad with a gold bump electrode formed thereon and with a copper wire stitch bonded to the gold bump electrode.

FIG. 4 is a detail sectional view of a bonding pad having a copper ball bond formed thereon with a copper wire extending from the ball bond.

FIGS. 5-15 are schematic illustrations of a sequence of operations performed in connection of a bonding pad on one die to a bonding pad on another die.

FIG. 16 is a flow chart illustrating a method of interconnecting first and second semiconductor dies.

### DETAILED DESCRIPTION

As used in this application, the term “gold wire” means a wire that is at least 50% pure gold by weight. “Gold bump electrode” refers to a bump electrode that is at least 50% pure gold by weight. Similarly, “copper wire” refers to a wire that is at least 50% pure copper by weight and “copper ball” refers to a ball that is at least 50% pure copper by weight.

As noted previously, dies of a multiple chip module (MCM) have conventionally been connected by thin gold wires which are bonded at opposite ends thereof to a bonding pad on each of the dies. Because of the high cost of gold relative to copper, applicants have attempted to interconnect bonding pads on dies in MCM's using copper wire, which is attached between bonding pads in the same manner in which gold wires are currently attached. In other words, a copper bump electrode is formed on the contact pad of a first die. Then a copper wire is ball bonded to the contact pad of a second die. Next the copper wire is extended from the point where it is attached to the ball bond to the bump electrode on the other contact pad. The copper wire is then stitch bonded to the copper bump electrode by application of pressure, heat and ultrasonic vibration. Applicants discovered that MCM's having dies thus interconnected with copper wires were far less expensive to produce, but also suffered from a high failure rate. Applicants also determined that the primary reason for this high failure rate is oxidation of the copper bump electrodes. Applicants also discovered that it is possible to produce MCM's at relatively low cost with relatively low failure rates by replacing the copper bump electrodes with gold bump electrodes to which copper wires are stitch bonded.

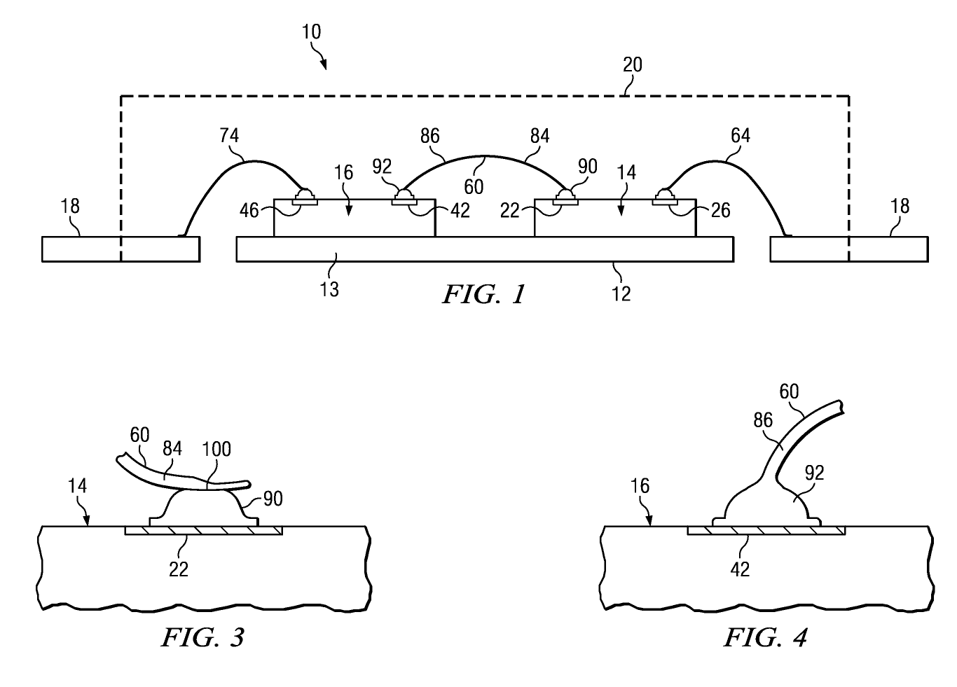

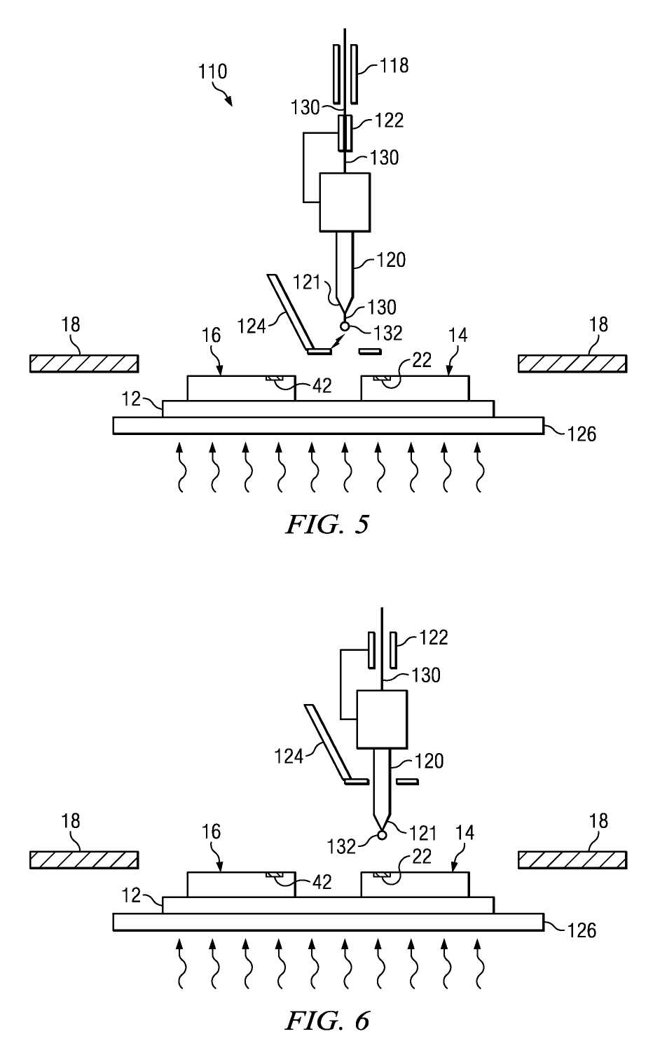

FIGS. 1-4, in general, illustrate an integrated circuit device, such as an MCM 10, that includes a first die 14 with a bonding pad 22 formed thereon. A gold bump electrode 90 is formed on the bonding pad 22. A copper wire 60 has an end portion 84 which is connected by a stitch bond 100 to the gold bump electrode 90. FIGS. 5-16 illustrate a method of interconnecting first and second semiconductor dies 14, 16. The method, in general, as set forth in FIG. 16, includes forming a gold bump electrode 90 on a bonding pad 22 of a first die 14 and stitch bonding a first end portion 84 of a copper wire 60 to the gold bump electrode 90.

FIG. 1 is a cross sectional view of a multi-chip module (MCM) 10. The MCM 10 includes a substrate which may be a lead frame 12 upon which a first die 14 and a second die 16 are mounted. The lead frame 12 may include a die pad portion 13 and a plurality of lead fingers 18 separated from and projecting outwardly from the die pad portion 13. The first and second dies 14, 16 and portions of the lead frame 12 may be enclosed in encapsulant 20 which may comprise, for example, transfer mold compound. First die 14 and second die 16 have bonding pads 22, 42, respectively, formed on top portions thereof. A first copper wire 60 electrically connects the first die bonding pad 22 to the second die bonding pad 42. Copper wire 60 has a first end portion 84 positioned proximate the first die bonding pad 22 and a second end portion 86 positioned proximate the second die bonding pad 42. A gold bump electrode 90 is bonded to the first die bonding pad 22. A copper ball 92 is ball bonded to the second die bonding pad 42. Copper ball 92 is integrally connected to the copper wire second end portion 86 as shown in detail in FIG. 4. As shown in detail in FIG. 3, gold bump electrode 90 and the first end portion 84 of copper wire 60 are connected by a stitch bond 100.

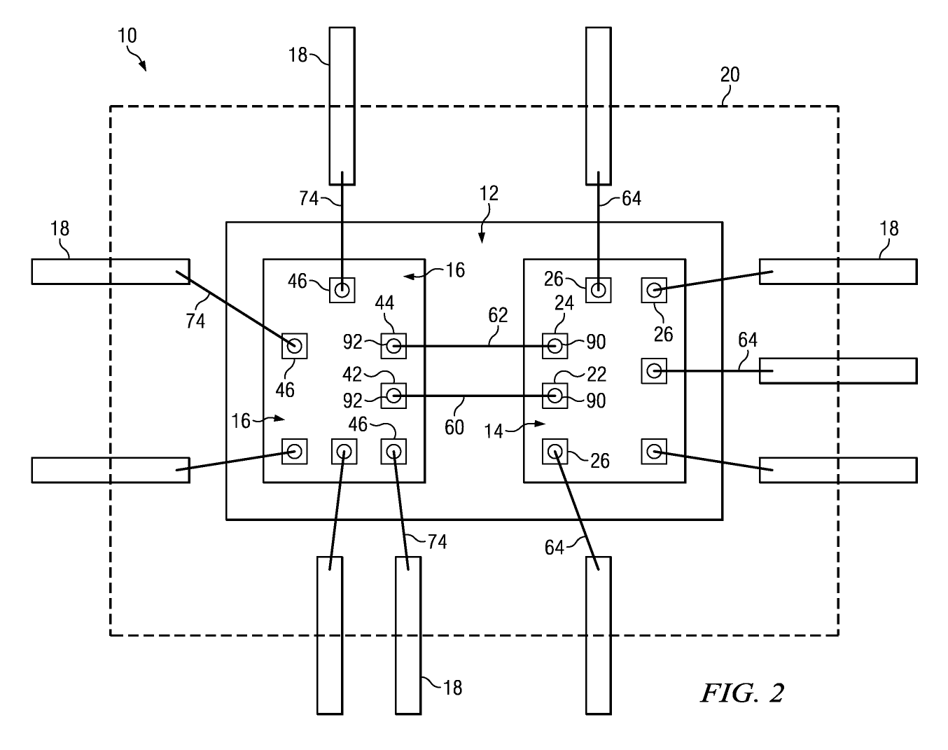

As best illustrated by FIG. 2, the first die 14 may have multiple bonding pads in addition to first die bonding pad 22. Additional bonding pads may include a bonding pad 24 which, like bonding pad 22, may have a gold bump electrode 90 formed thereon. The gold bump electrode 90 is stitch bonded to a copper wire 62. The wire 62 extends to the bump electrode 90 from a ball bond 92 on second die bonding pad 44. The first die 14 may include a plurality of other bonding pads 26. The second die may include a bonding pad 44 having a copper ball bond 92 formed thereon from which copper wire 62 extends. The second die 16 may also include further bonding pads 46. These additional bonding pads 26, 46 on the two dies may be connected by additional copper wires 64, 74 to the plurality of substrate leads 18. The copper wires 64, 74 may be ball bonded to respective bonding pads 26, 46 and may be attached by stitch bonding to substrate leads 18.

The method by which first die bonding pad 22 is electrically connected to second die bonding pad 42 will now be described in detail with reference to FIGS. 5-15. The bonding pads 22, 42 in one embodiment are made of aluminum or palladium plated aluminum. As shown by FIG. 5, the lead frame 12 upon which the first and second dies 14, 16 are mounted is placed in a bonding machine or bonder 110. The bonder 110 includes a wire source 118 from which a thin gold wire 130 is dispensed. A clamper 122 may be clamped on the thin wire 130 and displaced downwardly to pull it from the wire source 118 and into and through a capillary 120. Capillary 120 terminates in a small tip 121 with a hole in it (not shown) from which the gold wire 130 is dispensed. A wire heater 124 such as a blow pipe is used to heat the wire 130 extending from tip 121. The lead frame 12 on which the first and second dies 14, 16 are mounted is placed on a bonder machine pedestal 126 which supports the lead frame 12 and which may selectively apply heat thereto. A transducer (not shown), incorporated into the bonder 110 is used to selectively provide ultrasonic vibration, which facilitates various bonding operations as described in detail below. A well known and commercially available bonder that may be operated at the example parameter values described below is the KNS (Kulicke & Soffa) bonder. (One feature of this bonder is a capillary force indicator that indicates force in grams force. Example force values provided herein are indicated in grams force, which is abbreviated as “g.”) It will be understood by those skilled in the art that various other bonders may be used, with suitable adjustments made to the various specific parameters indicated below. Such adjustments may be determined empirically. The functional features of a bonder 110, which include the above described components as well as vision systems and various other robotics (not shown) are well known in the art. FIG. 5 illustrates the formation of a gold ball 132 at an end of gold wire 130 which protrudes from the capillary tip 121. The ball is formed as a result of heat applied by blow pipe 124 which may elevate the temperature of the gold wire 130 to its melting point (around 1000° C.).

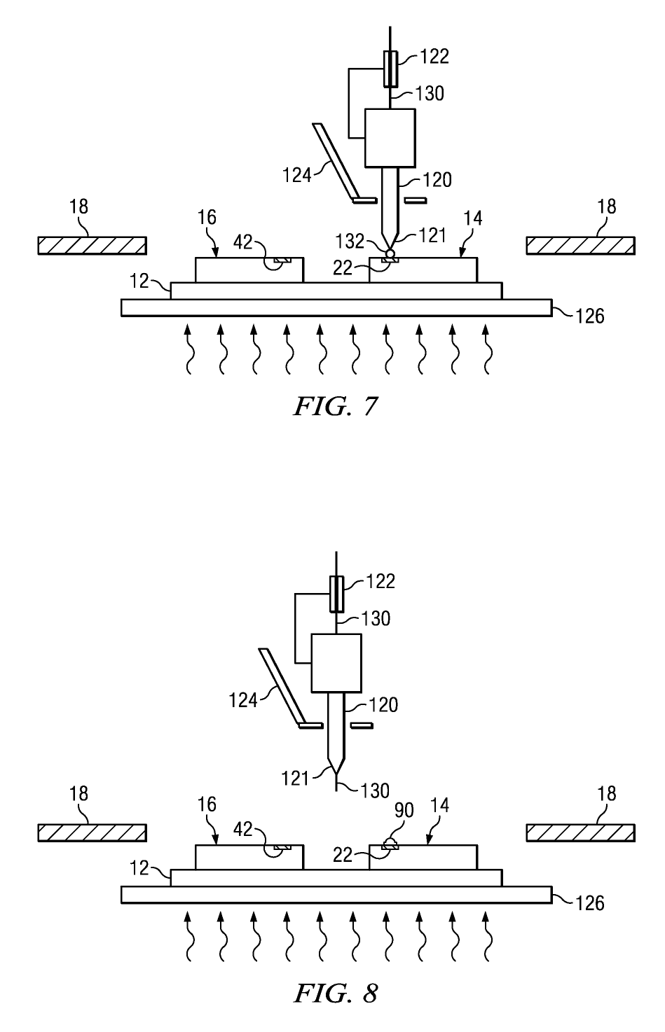

As illustrated by FIG. 6, the capillary 120 with a gold ball 132 formed at the capillary tip 121 may next be moved laterally to a position directly above bonding pad 22 of first die 14. At this point in time, the clamper 122 is no longer engaging gold wire 130. Next, as illustrated in FIG. 7, the capillary 120 may be moved downwardly until ball 132 engages bonding pad 22. The gold ball 132 is pressed against the bonding pad 22 under a predetermined force, which in one embodiment may be about 20 g, applied from above by capillary tip 121. The bonding pad 22 may itself be heated by heat applied from bonder pedestal 126 to a temperature of about 240° C. Also, ultrasonic vibration may be applied to the gold ball 132 and bonding pad 22 as by the bonder transducer. For example, the vibrating energy may be provided by an electric current of about 75 mAmp which is supplied to the transducer for about 15 msec.

In one embodiment, the composition of the gold wire 130 is 99.99% pure gold and 10-20 ppm (parts per million) silver, 6-10 ppm beryllium, and 20-32 ppm calcium, and may have a diameter of about 24.3 μm. The force applied to ball 132 by tip 121 may be about 20 g. As shown by FIGS. 7 and 8, the application of pressure, heat and ultrasonic vibration causes the gold ball 132 to be bonded to bonding pad 22 to form a gold bump electrode 90. Prior to displacing the capillary 120 from the position shown in FIG. 7 to the position shown in FIG. 8, the clamper 122 is clamped down on wire 130 preventing the wire from being displaced as the capillary 120 is moved. Thus the gold wire 130 is fractured near the top of the gold bump electrode 90 as the capillary 120 is displaced from the position shown in FIG. 7.

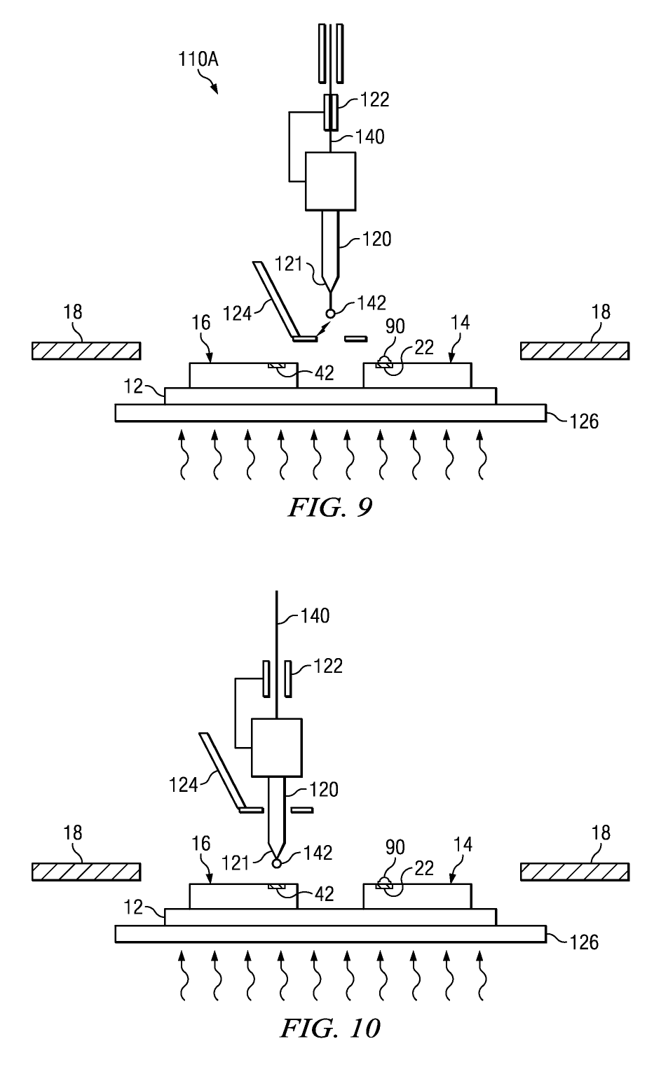

As illustrated by FIG. 9, the lead frame 12 and dies 14, 16 mounted thereon are next moved from gold bonder 110 to a copper bonder 110A. Copper bonder 110A may have the same operating components as the previously described gold bonder 110. The same reference numerals used for components of bonder 110 will also be used for components of bonder 110A. One difference between bonders 110 and 110A is, of course, the use of a copper wire 140, rather than a gold wire 130. The composition of the copper wire in this embodiment may be about 99.99% pure copper, <12 ppm silver, <6 ppm sulfur and <5 ppm iron. The copper wire may have a diameter of 24.3 μm. Initially, as illustrated in FIG. 9, a copper ball 142 is formed at an end portion of wire 140 below capillary tip 121. The copper wire 140 may be heated by blow pipe 124 to a temperature of about 1000° C. in order to form copper ball 142. Continued heating of the copper ball causes the ball to grow in size and be positioned at tip 121 of the capillary which is next moved laterally into position directly above bonding pad 42 of second die 16, FIG. 10.

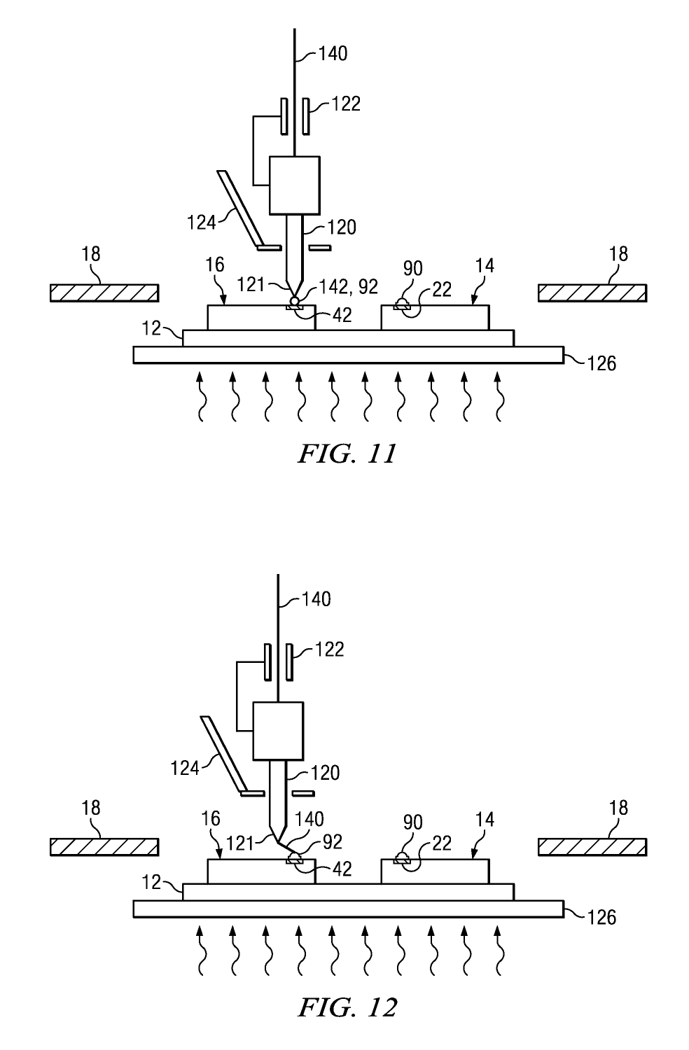

Next, as illustrated by FIG. 11, the capillary 120 is moved downwardly until ball 142 is engaged with the upper surface of bonding pad 42. Downward pressure is applied onto copper ball 142 by the capillary tip 121 at the same time die 16 is heated by heat applied from the bonder pedestal 126. Ultrasonic energy may also be applied to the ball 142 and pad 42. In one embodiment, the die 16 is heated to a temperature of around 240° C. and the force applied by tip 121 to ball 142 is around 20-50 g. The current driving the ultrasonic transducer may be around 60-80 mAmp and may be applied for about 15-20 msec. The pressure, heat and vibration energy applied to copper ball 142 and bonding pad 42 cause copper ball 142 to become a bond ball 92 which is fixedly bonded to the bonding pad 42.

Next, as illustrated by FIG. 12, the capillary 120 is moved upwardly and laterally relative to the bonding pad 42 with the clamper 122 released from engagement with copper wire 140 thereby allowing wire 140 to remain connected to ball bond 92 and to pay out from capillary 120.

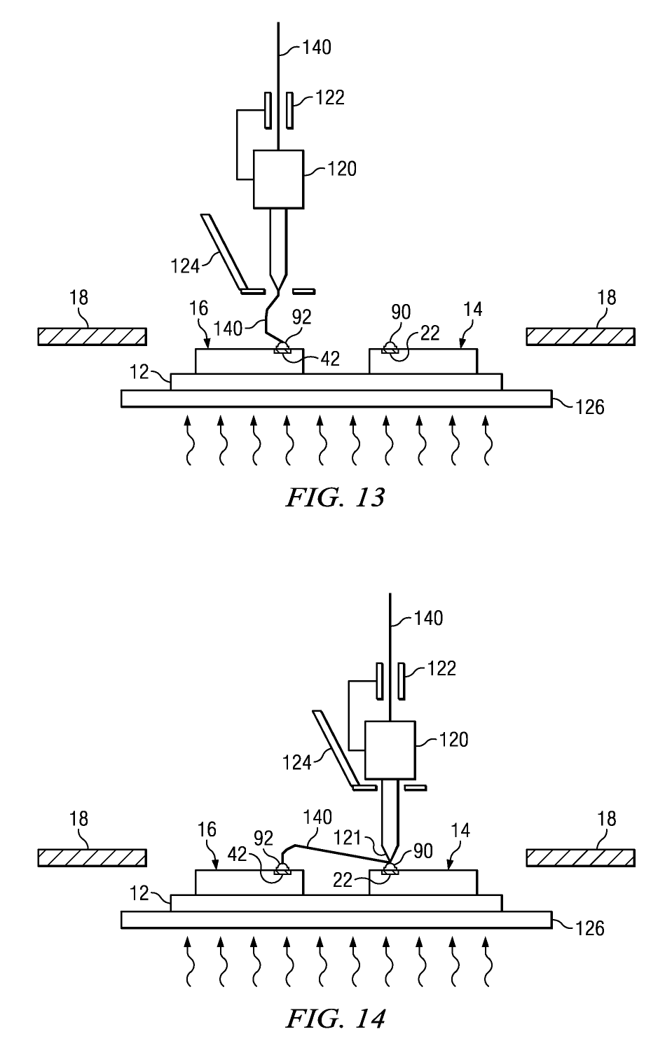

As illustrated by FIG. 13, copper wire 140 continues to be paid out as the capillary 120 is moved upwardly and then, as illustrated by FIG. 14, laterally and downwardly to a position in engagement with the top of gold bump electrode 90. (Although certain specific capillary movement patterns have been described herein to aid understanding the methodology, it will be appreciated by those skilled in the art that these movement patterns may be varied depending upon the desired shape of the bonding wire and/or other considerations.) Copper wire 140 is then stitch bonded to gold bump electrode 90, as through application of downward pressure by capillary tip 121, application of heat from bonder pedestal 126 and application of ultrasonic energy. In one embodiment, the amount of force applied by capillary tip 121 may be about 25 g, the temperature of the gold bump electrode 90 and the portion of copper wire 140 engaged therewith may be about 240° C. and the amplitude of vibration transducer current may be about 15 mAmp applied for about 10 msec.

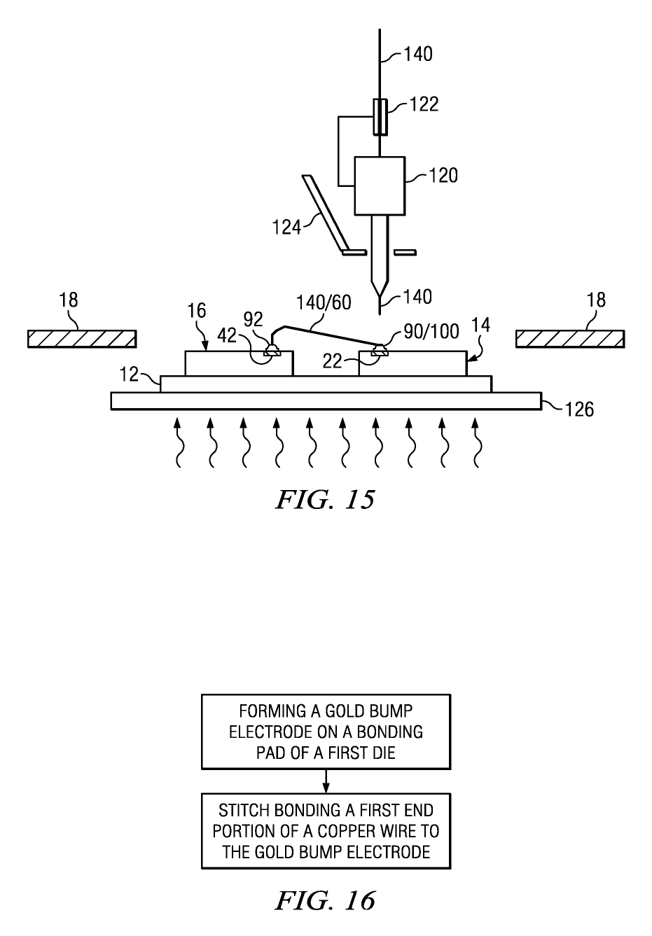

Next, as illustrated by FIG. 15, clamper 122 engages copper wire 140 pulling it upwardly until it ruptures and separates from the portion that is stitch bonded to the gold electrode bump 90, thus completing the copper wire stitch bond 100 on the gold bump electrode 90.

Other embodiments of a multiple chip module 10 may use different metal compositions and wire sizes in the gold and copper wires 130, 140. In such different embodiments, different bond formation parameters may be required as will be appreciated by those having skill in the art. For example, in an embodiment in which the gold wire 130 has a diameter of 33.3 μm and has a metal composition of 99.99% pure gold, <50 ppm silver, <10 ppm copper, 8-10 ppm beryllium, and <10 ppm lead, the force applied by capillary tip 121 when forming the gold bump 90 may be about 35 g. During bump formation, the temperature of the gold bump 90 and bonding pad 22 may be 240° C. and the ultrasonic transducer current may be about 90-100 mAmp for about 15 msec. In this embodiment, the copper wire 140 may have a diameter of 50.3 μm and may have a composition of 99.99% pure copper, <1 ppm silver, <1 ppm calcium, <1 ppm iron, <1 ppm magnesium, and <1 ppm manganese. The force applied by the capillary tip 121 to form copper ball bond 92 on bonding pad 42 may be 50-70 g and the heat of the ball bond 92 and bonding pad 42 may be about 240° C. The transducer current may be 120-160 mAmp for a period of about 15 msec. In order to form stitch bond 100, the force applied by capillary tip 121 may be about 45 g and the gold electrode bump 90 and copper wire 140 used to form the stitch bond 100 may be heated to about 240° C. The ultrasonic transducer current may be 30 mAmp applied for a duration of about 10 msec.

Thus, two specific embodiments have been described of methods for connecting bonding pads on different dies with a copper wire that is ball bonded to one bonding pad and stitch bonded to a gold bump electrode on the other bonding pad. In such methods, in general, the copper wire used may have a diameter in a range from about 15 μm to about 60 μm; the temperature at which the copper wire is stitch bonded to the gold bump electrode may be between about 150° C. and about 280° C.; the force urging the copper wire against the gold bump electrode may be between about 10 g and 100 g; the copper wire and the gold bump electrode may be vibrated by a bonder ultrasonic transducer. The ultrasonic transducer may receive an electric current of between about 10 mAmp and 100 mAmp; the gold bump electrode is typically at least 99% pure gold and the copper wire is typically at least 99% pure copper. However, it will be appreciated by those skilled in the art after reading this disclosure that various other parameter values may be used depending upon, among other things, wire diameter and composition and the particular bonder that is used.

While various embodiments of the invention have been specifically described herein, it will be obvious to those having skill in the art that the invention may be otherwise variously embodied. The appended claims are to be construed to cover all such alternative embodiments except to the extent limited by the prior art.

What is claimed is:

1. An integrated circuit (IC) device comprising:
a first die;
a first die bonding pad formed on said first die;
a gold bump electrode formed on said first bonding pad; and
a copper wire comprising a first end portion stitch bonded to said gold bump electrode.

2. The IC device of claim 1 further comprising:
a second die;
a second die bonding pad formed on said second die; and
wherein said copper wire comprises a second end portion ball bonded to said second die bonding pad.

3. The IC device of claim 2 further comprising a substrate and wherein said first die and said second die are mounted on said substrate.

4. The IC device of claim 3 wherein said substrate comprises a leadframe.

5. The IC device of claim 3 further comprising encapsulant that encapsulates said first and second dies and said wire.

6. The IC device of claim 1 wherein:
a plurality of first die bonding pads are formed on said first die;
a plurality of second die bonding pads are formed on said second die;
a plurality of gold bump electrodes are formed on said plurality of first die bonding pads;
a plurality of copper wires electrically connect said plurality of second die bonding pads to said plurality of gold bump electrodes.

7. The IC device of claim 1 wherein said gold bump electrode is at least 99% pure gold.

8. The IC device of claim 1 wherein said copper wire is at least 99% pure copper.

9. The IC device of claim 1 wherein said first die bonding pad comprises aluminum or palladium plated aluminum.

10. A method of interconnecting first and second semiconductor dies comprising:
forming a gold bump electrode on a bonding pad on the first die; and
stitch bonding a first end portion of a copper wire to the gold bump electrode.

11. The method of claim 10 comprising ball bonding a second end portion of the copper wire to a contact pad of the second die.

12. The method of claim 11 comprising mounting the first and second dies on a substrate.

13. The method of claim 12 comprising encapsulating the first and second dies, the gold bump electrode and the copper wire.

14. The method of claim 10 wherein said forming a gold bump electrode on a bonding pad of the first die comprises forming a gold bump electrode on an aluminum or palladium plated aluminum bonding pad.

15. The method of claim 14 wherein said stitch bonding a first end portion of a copper wire to the gold bump electrode comprises stitch bonding a first end portion of a copper wire that has a diameter in a range from 15 μm to 60 μm.

16. The method of claim 15 wherein said stitch bonding a first end portion of a copper wire to the gold bump electrode comprises heating the copper wire and the gold bump electrode to between 150° C. and 280° C.

17. The method of claim 16 wherein said stitch bonding a first end portion of a copper wire to the gold bump electrode comprises urging the copper wire against the gold bump electrode at a force of between about 10 g and 100 g.

18. The method of claim 17 wherein said stitch bonding a first end portion of a copper wire to the gold bump electrode comprises vibrating the copper wire and the gold bump electrode with an ultrasonic transducer receiving an electric current of between about 10 mAmp and 100 mAmp.

19. The method of claim 10 wherein said forming a gold bump electrode on a bonding pad on the first die comprises forming a gold bump electrode that is at least 99% pure gold by weight and wherein said stitch bonding a first end portion of a copper wire to the gold bump electrode comprises stitch bonding a first end portion of a copper wire that is at least 99% pure copper by weight.

20. A multichip module comprising:
a first die;
a first die bonding pad formed on said first die;
a gold bump electrode formed on said first bonding pad;
a second die;
a second die bonding pad formed on said second die;
a copper wire comprising a first end portion stitch bonded to said gold bump electrode and a second end portion ball bonded to said second die bonding pad;
said first and second die pads, said gold bump electrode and said copper wire being enclosed in encapsulant.
